(19) United States
(12) Patent Application Publication
(10) Pub. No.: US 2008/0043513 A1
(43) Pub. Date: Feb. 21, 2008

(54) INTERGRATED CIRCUIT HAVING MEMORY WITH RESISTIVE MEMORY CELLS

(76) Inventors: Heinz Hoenigschmid, Poecking (DE); Michael Angerbauer, Munich (DE); Corvin Liaw, Munich (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/466,072

(22) Filed: Aug. 21, 2006

(51) Int. Cl. G11C 7/10; G11C 11/00; G11C 7/02; G11C 7/06

(52) U.S. Cl. 365/148; 365/163; 365/208; 365/189.07; 365/189.06

(57) ABSTRACT

A memory device, and method of operating the same, wherein the device includes resistive memory cells being switched between a low-resistive state and a high-resistive state; an evaluation unit, being coupled to a resistive memory cell to determine a resistive state of the resistive memory cell; and a voltage regulation circuit, being coupled to the resistive memory cell and to the evaluation unit. The voltage being applied to the resistive memory cell is regulated with respect to a target voltage.

### BACKGROUND OF THE INVENTION

1. Field of the Invention

The invention relates to a memory device comprising resistive memory cells. The invention also relates to a method of evaluating the resistive state of a resistive memory cell.

2. Description of the Related Art

Demands imposed on large scale integrated electronic circuits are constantly increasing. To ensure the economic success of such electronic circuits, such as electronic data memories, programmable logic modules, or microprocessors, ongoing development is aimed mainly at structure density, speed, and, in the case of electronic data memories, at the so-called volatility. The latter volatility is a figure of how long an electronic data memory may reliably hold a stored item of information without the need of an external supply of energy.

Whereas volatile memories, such as a DRAM (Dynamic Random Access Memory), store information only for short time, and, therefore, have to be continuously refreshed, the semiconductor industry has also developed a range of non-volatile memories, such as the Flash RAM. Although a Flash RAM reliably retains the information stored in it for several years without an external energy supply, a large amount of energy is required to write information into a Flash RAM and the required voltages are often above the voltage levels of common battery power supplies.

As a result, substantial scientific and industrial research effort is made to develop new concepts for non-volatile memories. A prominent example of a modern non-volatile memory is an electronic data memory with resistive memory cells. These resistive memory cells change their electric resistance by means of the application of electric signals, while the electric resistance remains stable in the absence of any signals. In this way, such a memory cell may store two or more logic states by a suitable programming of its electronic resistance. A binary coded memory cell may then, for example, store an information state “0” by assuming a high resistive state, and an opposite information state “1” by assuming a low resistive state.

Promising concepts for such resistive memory cells include magneto-resistive memory cells, phase change memory cells, and conductive bridging memory cells. A suitable material system for the latter conductive bridging memory cells, which are already subject to intense industrial research and development, are the so-called solid electrolytes. In such materials a conductive path may be formed by means of the application of electric signals. The switching mechanism is based on the polarity dependent electrochemical deposition and removal of a metal in a thin solid state electrolyte film.

In this concept, the ON-state is achieved by applying a positive bias at the oxidizable anode resulting in a redox reaction, driving, for example, Ag ions into a chalcogenide glass, for example germanium selenide. This leads to the formation of metal rich clusters, which form a conductive bridge between both electrodes. The device may be switched back to the OFF-state by applying an opposite voltage. In this case, the metal ions are removed, which in turn erases the conductive bridge. Once a continuous path of ions is formed, this path may short circuit the otherwise high resistive solid electrolyte between two electrodes, hence drastically reducing the effective electric resistance. For the realization of solid electrolyte resistive memory cells the application of so-called chalcogenide materials, such as Germanium, Selenium, Sulfur, etc., are already common.

Since both the programming and the evaluation of a resistive state of a resistive memory cell is often conducted by means of the same set of two electrodes, care must be taken to apply appropriate voltage levels, and to avoid a modification of a stored state by a reading operation. In general, the required voltages for programming, i.e. for formation or decomposition of conductive paths, are higher than the voltage levels which suffice to evaluate the resistive state of a resistive memory cell. Since resistive memory cells assume distinguishable resistive states which may differ substantially by 6 to 7 orders of magnitude, the application of a well defined sense voltage may be subject to substantial alterations caused by the possible difference of the resistance. On the other hand, a reliable application of a well defined and reproducible sense voltage is necessary for a proper and reliable evaluation of the resistive state of the resistive memory cell. Often a constant voltage is applied to the resistive memory cell, causing a current dependent on the resistance of the resistive memory cell, which is, in turn, sensed by a voltage drop at a shunt resistance. As a consequence, a variation in the reading voltage may result in an unreliable evaluation outcome.

Conventional memory devices with resistive memory cells may comprise a voltage limiting circuit that limits the voltage which is applied to the resistive memory cell. Assuming a sufficient input voltage and a minimum resistance of the resistive memory cell, the voltage limiting circuit may provide a constant and well defined sense voltage.

### SUMMARY OF THE INVENTION

Various aspects of the present invention can provide particular advantages for an improved resistive memory cell, an improved integrated circuit, and an improved method of evaluating the resistive state of a resistive memory cell.

For one embodiment of the present invention, a memory device comprises resistive memory cells being switched between a low-resistive state and a high-resistive state; an evaluation unit, being coupled to a resistive memory cell to determine a resistive state of the resistive memory cell; and a voltage regulation circuit, being coupled to the resistive memory cell and to the evaluation unit, and regulating the voltage being applied to the resistive memory cell to a target voltage.

For one embodiment of the present invention, a memory device, comprises resistive memory cells, being switched between a low-resistive state and a high-resistive state and being coupled to a word line, to a bit line, and to a reference electrode, wherein the resistive memory cells comprise a resistive memory element and a selection transistor; an evaluation device to determine a resistive state of a resistive memory cell; and a voltage regulation circuit, being arranged in between said evaluation device and said memory cells, being coupled to said evaluation device via a signal line, being coupled to the bit line, and being further coupled to the bit line between the voltage regulation circuit and the resistive memory cells via a feedback line, and regulating the voltage being applied to the resistive memory cell to a target voltage.

For one embodiment of the present invention, an integrated circuit comprises a programmable resistance element being switched between a low-resistive state and a high-resistive state; and a voltage regulation circuit, being coupled to the programmable resistance element and regulating the voltage being applied to the resistive memory cell to a target voltage.

For one embodiment of the present invention, a method of evaluating the resistive state of a resistive memory cell comprises the steps of applying a sense voltage to the resistive memory cell; measuring the applied sense voltage at the resistive memory cell; comparing the measured sense voltage to a reference voltage; and controlling the sense voltage to a target voltage.

### BRIEF DESCRIPTION OF THE DRAWINGS

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1A shows a schematic view of an evaluation unit, a voltage regulation circuit, and a resistive memory cell, according to a first embodiment of the present invention;

FIG. 1B shows a schematic view of an evaluation unit, a voltage regulation circuit, and a resistive memory cell, according a second embodiment of the present invention;

FIG. 1C shows a schematic view of an evaluation unit, a voltage regulation circuit, a multiplexing unit, and resistive memory cells according to a third embodiment of the present invention;

FIG. 1D shows a schematic view of an evaluation unit, a voltage regulation circuit, a multiplexing unit, and resistive memory cells according to a fourth embodiment of the present invention;

FIG. 2 shows a schematic view of an evaluation unit, a voltage regulation circuit, a multiplexing unit, and a resistive memory cell, according to a fifth embodiment of the present invention;

FIG. 3 shows a schematic view of a memory device comprising resistive memory cells according to a sixth embodiment of the present invention; and

FIG. 4 shows a schematic view of an operational amplifier and a resistive memory cell according to a seventh embodiment of the present invention.

### DETAILED DESCRIPTION OF THE PREFERRED EMBODIMENT

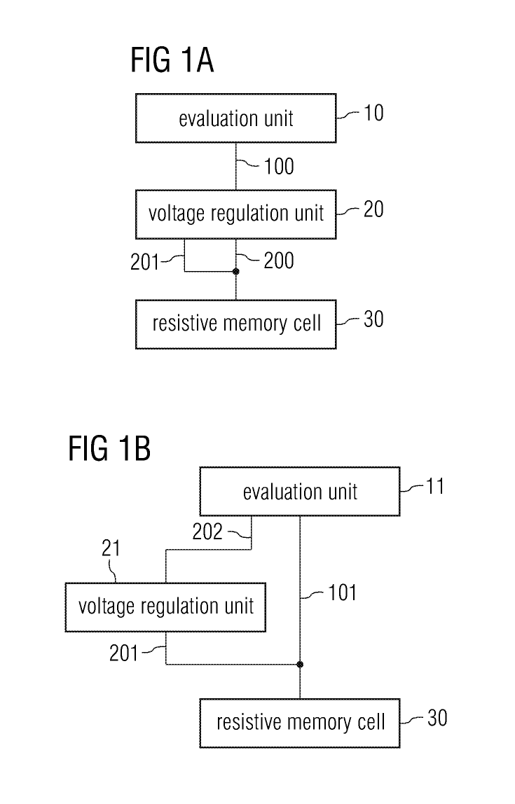

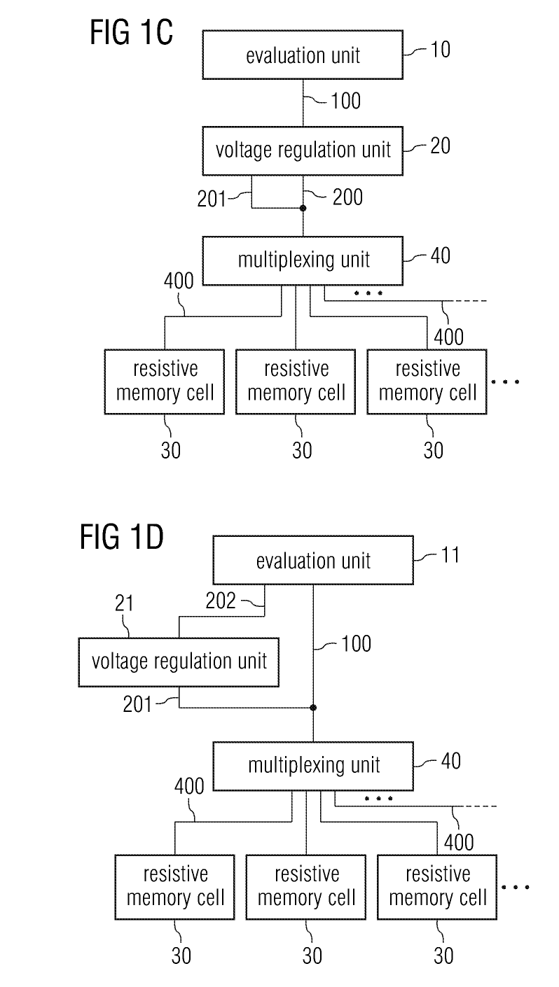

FIG. 1A shows a schematic view of an evaluation unit 10, a voltage regulation circuit 20, and a resistive memory cell 30, according to a first embodiment of the present invention. The resistive memory cell 30 may assume two or more distinguishable resistive states, in this way representing two or more logical states. As an example, a low resistive state may correspond to a logical state “1”, whereas a high resistive state may correspond to a logical state “0”. The resistive memory cell may be based on conductive bridging, phase changing, magnetoresistance, or any other concept for achieving a stable memorization of an electrical resistance. For a reliable distinction between resistive states, the electrical resistance may vary in a sufficient range. In the case of a conductive bridging storage element, variations of the electric resistance by 6 to 7 orders of magnitude may be common. In such a case, a low resistive state may be defined for a resistive memory cell having an effective resistance of approximately 10 kΩ, whereas a high resistive state may correspond to an effective electric resistance of 1 GΩ.

The evaluation of the resistive state of a resistive memory cell is generally effected by means of an application of electric signals during a reading operation. During such a reading operation the resistance is sensed and a corresponding logic state, for example for a binary cell one out of “0” and “1”, is determined. The voltage regulation unit 20 applies a sensing voltage via a bit line 200 to the resistive memory cell 30. If the applied voltage at the resistive memory cell 30 remains essentially constant, the evaluation unit 10 may determine the resistive state of the resistive memory cell 30 by measuring the resulting current via a signal line 100. According to this embodiment of the present invention, a voltage regulation circuit 20 is arranged in between the evaluation unit 10 and the resistive memory cell 30. The signal line 100 is hence connected from the evaluation unit 10 to the voltage regulation circuit 20. The voltage regulation circuit 20 regulates the voltage and applies the regulated voltage via a bit line 200 to the resistive memory cell 30. For the regulation of the applied voltage the voltage regulation circuit 20 senses the actually applied voltage at the bit line 200 via a feedback line 201. Being able to determine the actual voltage via the feedback line 201, the voltage regulation circuit 20 regulates the incoming voltage from the bit line 200 and ensures that the applied voltage is maintained sufficiently constant at the resistive memory cell 30.

Since the effective electric resistance of the resistive memory cell 30 may vary dramatically, according to the respective resistive state of the resistive memory cell 30, the voltage applied to it may be subject to undesired changes. In the case that the resistive memory cell 30 is in a high resistive state, the sense voltage coming from the voltage regulation unit 20 via the bit line 200 may correspond approximately to the target voltage at the resistive memory cell, since the high resistance of the resistive memory cell 30 prevents a critical voltage drop, since only a little current is drawn from the voltage source. On the other hand, however, in the case that the resistive memory cell 30 is in a low resistive state, a substantial voltage drop may occur. In this case, according to this embodiment of the present invention, the voltage regulation circuit 20 senses the actual voltage via the feedback line 201 and regulates the voltage to a target voltage. In one embodiment, the voltage is raised to the target voltage in case a voltage drop caused a deviation from the target voltage. In one embodiment, the actual voltage at the resistive memory cell 30 is kept essentially constant corresponding to a target voltage level over the entire effective range of resistance of the resistive memory cell 30. According to one embodiment, the target voltage is in a range of ±30% of the voltage being applied in the case of the resistive memory cell 30 being in a high resistive state. According to a further embodiment, the target voltage is in a range of ±15% of the voltage being applied in the case of the resistive memory cell 30 being in a high resistive state, and, according to yet another embodiment, the target voltage is in a range of ±8% of the voltage being applied in the case of the resistive memory cell 30 being in a high resistive state.

As an example, the resistive memory cell 30 may comprise a conductive bridging element which may comprise a chalcogenide. In such a material the threshold voltage for changing the resistive state of the resistive memory cell 30 may be in a range of 200 to 250 mV. As a result, the applied voltage for evaluating the resistive state, without substantially altering the resistive state, may be well below this threshold voltage. For example, a reading voltage in a range of 100 to 150 mV may be applied to determine the resistive state of the resistive memory cell 30. In this case, the voltage regulation unit 20 may apply a sense voltage in the range of 100 mV to 150 mV to the resistive memory cell being either in a low resistive state or high resistive state. The sense voltage may drop substantially below the range of 100 mV to 150 mV where the resistive memory cell is in a low resistive state. The voltage regulation circuit 20 may then regulate the voltage to a target voltage lying in said range, or with a tolerance of ±30% in said range. The tolerance may be decreased to ±15% or to ±8%. In principal, the voltage regulation circuit 20 may raise the applied voltage to just below the threshold voltage. Variations of the actually applied sense voltage over the entire resistive state of the resistive memory cell 30 may be in a range of ±30 mV, ±15 mV and ±8 mV, according to various embodiments.

FIG. 1B shows a schematic view of an evaluation unit 11, a voltage regulation circuit 21, and a resistive memory cell 30. According to a second embodiment of the present invention, the evaluation circuit 11 applies a sense voltage to the resistive memory cell 30 via a signal line 101. The voltage regulation circuit 21 senses the actually applied voltage at the resistive memory cell 30 via a feedback line 201 and controls the evaluation unit 11 via a control line 202. In this way, the applied voltage is regulated to a target voltage. The evaluation unit 11 may raise the applied voltage to a target voltage.

FIG. 1C shows a schematic view of an evaluation unit 10, a voltage regulation circuit 20, a multiplexing unit 40, and resistive memory cells 30, according to a third embodiment of the present invention. According to this embodiment, the master bit line 200 is shared by a plurality of resistive memory cells 30 via the multiplexing unit 40. The bit line 200 then acts as a master bit line. The multiplexing unit 40 connects the master bit line 200 to only one of the bit lines 400 at a time. In this way, the evaluation unit 10 and the voltage regulation circuit 20 may be shared by more than one resistive memory cell 30, which increases device efficiency, performance, and storage capacity.

FIG. 1D shows a schematic view of an evaluation unit 11, a voltage regulation circuit 21, a multiplexing unit 40, and resistive memory cells 30, representing a combination of the embodiments already described in conjunction with FIGS. 1B and 1C.

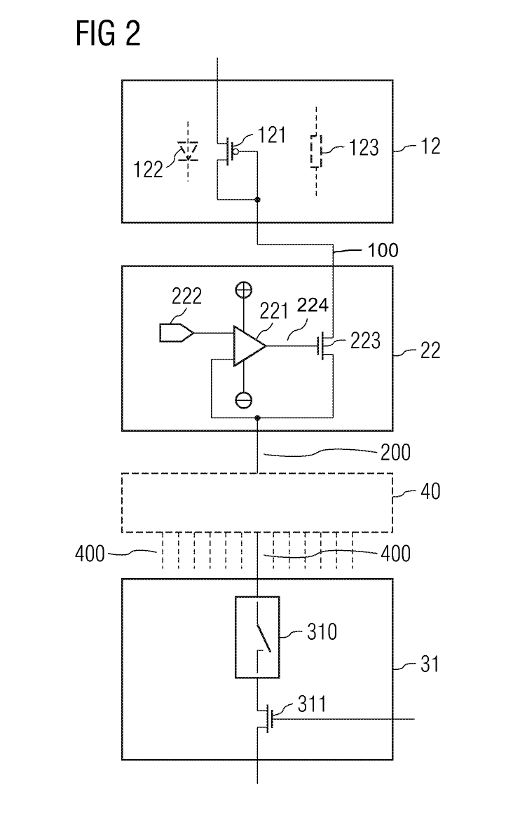

FIG. 2 shows a schematic view of an evaluation unit 12, a voltage regulation circuit 22, an optional multiplexing unit 40, and a resistive memory cell 31, according to a fifth embodiment of the present invention. The evaluation unit 12 may comprise a transistor 121, to convert a current flowing through the evaluation unit 12 to a voltage. The transistor 121 may act similarly to a diode 122 or to a resistor 123, at which a current may cause a voltage drop.

The sense voltage of the evaluation unit 12 is coupled to a voltage regulation circuit 22 via a signal line 100. The voltage regulation circuit 22 may comprise a regulation transistor 223. The regulation transistor 223 may be an n-channel FET. A gate of the regulation transistor 223 may be coupled via a line 224 to an output of an operational amplifier 221—or any other comparator circuit—which compares the applied voltage to a reference voltage 222. As being typical of such a circuitry, the operational amplifier 221 attempts to regulate the voltage being applied via the line 200 to the resistive memory cell 31 by comparing this voltage coupled to one input of the operational amplifier 221 to a reference voltage coupled to a second input of the operational amplifier 221. The latter reference voltage may be provided by a reference voltage source 222 or by the supply voltage by means of an optional voltage divider.

The resistive memory cell 31 may comprise a resistive memory element 310, comprising, for example, a chalcogenide or another solid electrolyte, or another conductive bridging material, and a selection transistor 311. The resistive memory element 310 is coupled via a bit line 200, 400 to the voltage regulation circuit 22 and to the selection transistor 311. The selection transistor 311 is furthermore coupled to a word line and a reference electrode. The resistive memory element 310 may further be arranged on the other side of the selection transistor 311, in this case the selection transistor 311 being coupled to the bit line 200, 400. Upon addressing the selection transistor 311 a current may flow from the output of the voltage regulation circuit 22 through the resistive memory element 310 and through the selection transistor 311 to a reference electrode. This current, being dependent on the applied voltage and the resistance of the resistive memory element 310, flows also through the voltage regulation circuit 22 and the evaluation unit 12. Hence, assuming that the voltage regulation circuit 22 sufficiently maintains the voltage being applied to the resistive memory cell 31, this current may be converted to an output signal of the evaluation unit 12. This output voltage then reliably corresponds to the resistive state of the resistive memory element 31.

An optional multiplexing unit 40 may be arranged in between the voltage regulation circuit 22 and a plurality of resistive memory cells 31 in order to share the evaluation unit 12 and a voltage regulation circuit 22 to more than one resistive memory cell 31. In the presence of a multiplexing unit 40, the bit line 200 may act as a master bit line and the voltage regulation circuit 22 is coupled to the multiplexing unit 40 via the master bit line 200, and is coupled to the resistive memory cell 31 via a bit line 400. In absence of the multiplexing unit 40, the voltage regulation circuit 22 is directly coupled to the memory cell 31 via a single bit line denoted by 200 and 400.

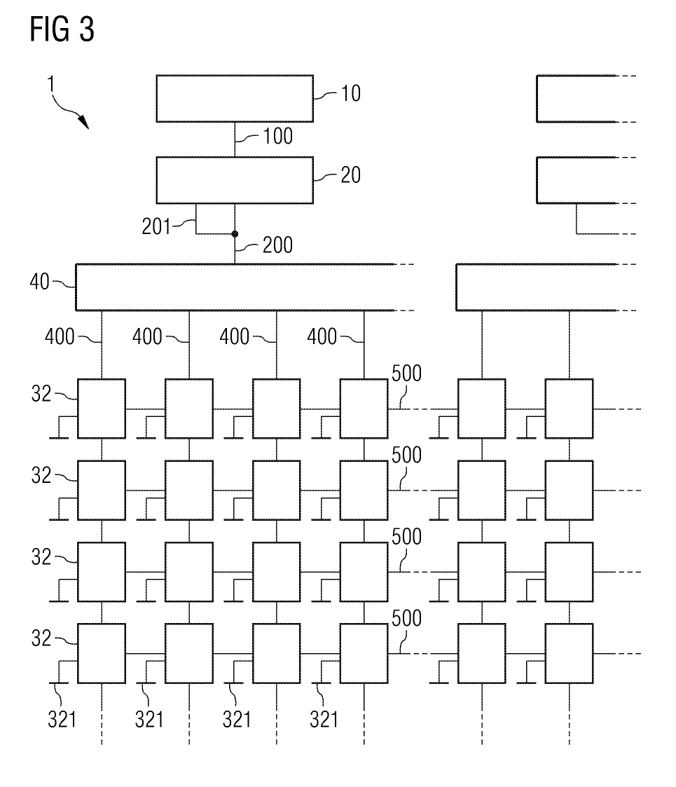

FIG. 3 shows a schematic view of a memory device 1 according to a sixth embodiment of the present invention. The memory device 1 comprises a plurality of resistive memory cells 32, being arranged in columns and rows. Said resistive memory cells 32 are coupled to bit lines 400, to word lines 500, and to a reference electrode 321. A plurality of bit lines 400 is shared by a multiplexing unit 40. Said multiplexing unit 40 connects one of the bit lines 400 to the master bit line 200 at a time. Usual arrangements include 4, 8, 16, 32, 64 and more bit lines 400 being multiplexed by a single multiplexing unit 40. A voltage regulation unit 20 applies a sense voltage via a signal line 200, said sense voltage being regulated by the voltage regulation circuit 20 via feedback loop 201 and being coupled to the multiplexing unit 40 by the master bit line 200. The voltage regulation circuit 20 senses the applied voltage via a feedback line 201 and regulates the voltage, when the voltage changes due to a change of the resistance of a resistive element 32. In case of a voltage drop, the voltage regulation circuit 20 may raise the applied voltage to a target voltage. Addressing of a respective memory cell 32 is effected by selecting the respective bit line 400 and the respective word line 500. The resistive memory cell 32 at these lines' crossing is then selected and a sense current may flow from the evaluation unit 10 via the voltage regulation circuit 20, the multiplexing unit 40 through the respective resistive memory cell 32 to the reference electrode 321.

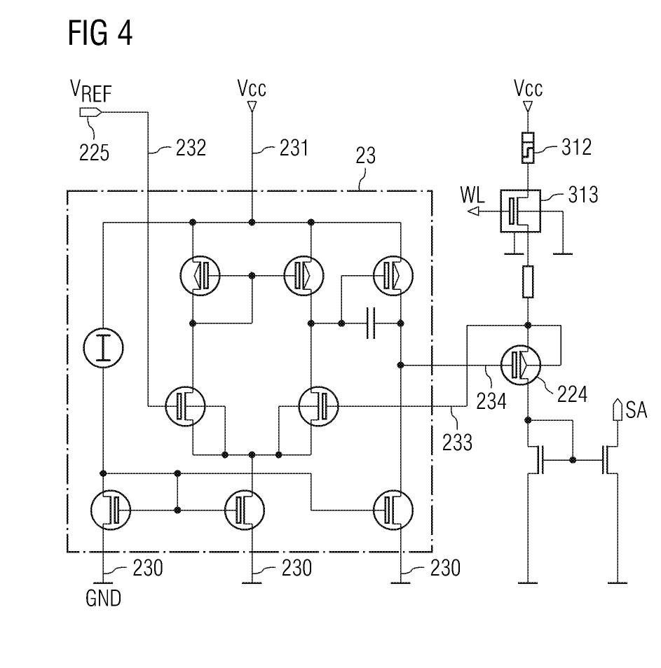

FIG. 4 shows a schematic view of an operational amplifier 23 and a resistive memory cell according to a seventh embodiment of the present invention. A resistive memory cell comprises a resistive memory element 312 and a selection transistor 313, which is coupled to a word line (WL). The voltage which is applied to the resistive memory cell, being a fraction of the potential difference between the ground potential (GND) and the supply voltage V_{CC}, is regulated by a regulation transistor 224. The gate of said regulation transistor 224 is coupled to an output 234 of the operational amplifier 23.

The operational amplifier 23, as shown here, may be a conventional operational amplifier and the actually shown circuitry is just one example for various known implementations and circuitries of operational amplifiers. The shown operational amplifier 23 is coupled to a supply voltage with a ground supply 230 and a supply voltage 231. One of the two inputs, here the input 232, is coupled to a reference voltage 225. The other input 233 is coupled to the voltage being applied at the point between the regulation transistor 224 and the resistive memory cell. In this way, the operational amplifier 23 regulates the applied voltage at the memory cell, by means of an appropriate control of the gate of the regulation transistor 224 via its output 234. The voltage being applied at the resistive memory cell is regulated to be equal to the reference voltage 225. An evaluation circuit may be provided which couples an output signal to a sense amplifier (SA) to determine the resistive state of the resistive element 312. The shown operational amplifier 23 acts as a differential amplifier, whose output 234 is proportional to the voltage between the two inputs 232 and 233.

The preceding description only describes advantageous exemplary embodiments of the invention. The features disclosed therein and the claims and the drawings can, therefore, be essential for the realization of the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A memory device, comprising:
a plurality of resistive memory cells configured to switch between a low-resistive state and a high-resistive state, each state corresponding to a respective binary value;
an evaluation unit coupled to at least one of the resistive memory cells to determine a resistive state of the resistive memory cell; and
a voltage regulation circuit coupled to the at least one resistive memory cell and to the evaluation unit, and configured to regulate a voltage applied to the at least one resistive memory cell with respect to a target voltage.

2. The memory device as claimed in claim 1, wherein the voltage regulation circuit raises the applied voltage to the resistive memory cell to the target voltage when the resistive memory cell is in the low-resistive state.

3. The memory device as claimed in claim 1, wherein the target voltage is in a range of ±30% of the applied voltage when of the resistive memory cell is in the high-resistive state.

4. The memory device as claimed in claim 1, wherein the target voltage is in a range of ±15% of the applied voltage when of the resistive memory cell is in the high-resistive state.

5. The memory device as claimed in claim 1, wherein the target voltage is in a range of ±8% of the applied voltage when the resistive memory cell is in the high-resistive state.

6. The memory device as claimed in claim 1, wherein the voltage regulation circuit is arranged in between the evaluation unit and the at least one resistive memory cell.

7. The memory device as claimed in claim 1, wherein the voltage regulation circuit comprises a comparator circuit which compares the applied voltage to a reference voltage to adjust the applied voltage.

8. The memory device as claimed in claim 1, wherein the voltage regulation circuit comprises an operational amplifier which compares the applied voltage to a reference voltage to adjust the applied voltage.

9. The memory device as claimed in claim 1, wherein the voltage regulation circuit comprises a feedback line which couples the applied voltage to the voltage regulation circuit.

10. The memory device as claimed in claim 1, wherein the voltage regulation circuit comprises a regulation transistor which regulates the coupling of the evaluation unit to the at least one resistive memory cell.

11. The memory device as claimed in claim 10, wherein the voltage regulation circuit further comprises an operational amplifier, a first input of the operational amplifier being coupled to the applied voltage via a feedback line, a second input of the operational amplifier being coupled to a reference voltage, and an output of the operational amplifier being coupled to a gate electrode of the regulation transistor.

12. The memory device as claimed in claim 1, wherein the memory device further comprises a multiplexing unit connected between the evaluation unit and plurality of resistive memory cells.

13. A memory device, comprising:
a plurality of resistive memory cells configured to switch between a low-resistive state and a high-resistive state and being coupled to a word line, to a bit line, and to a reference electrode, wherein the each of the resistive memory cells comprise a resistive memory element and a selection transistor;
an evaluation device to determine a resistive state of at least one of the resistive memory cells to which a voltage is applied; and
a voltage regulation circuit, arranged between the evaluation device and the memory cells, and coupled to the evaluation device via a signal line, and further coupled to the bit line between the voltage regulation circuit and the resistive memory cells via a feedback line, and regulating the applied voltage to the at least one resistive memory cell with respect to a target voltage.

14. The memory device as claimed in claim 13, wherein the voltage regulation circuit raises the applied voltage to the target voltage when the resistive memory cell is in the low-resistive state.

15. The memory device as claimed in claim 13, wherein the target voltage is in a range of ±30% of the applied voltage when the resistive memory cell is in the high-resistive state.

16. The memory device as claimed in claim 13, wherein the target voltage is in a range of ±15% of the applied voltage when the resistive memory cell is in the high-resistive state.

17. The memory device as claimed in claim 13, wherein the target voltage is in a range of ±8% of the applied voltage when the resistive memory cell is in the high-resistive state.

18. The memory device as claimed in claim 13, wherein the voltage regulation circuit comprises a comparator circuit which compares the applied voltage to a reference voltage to adjust the applied voltage.

19. The memory device as claimed in claim 13, wherein the voltage regulation circuit comprises an operational amplifier which compares the applied voltage to a reference voltage to adjust the applied voltage.

20. The memory device as claimed in claim 13, wherein the voltage regulation circuit comprises a regulation transistor which regulates the coupling of the evaluation unit to the at least one resistive memory cell.

21. The memory device as claimed in claim 20, wherein the voltage regulation circuit further comprises an operational amplifier, a first input of the operational amplifier being coupled to the applied voltage via a feedback line, a second input of the operational amplifier being coupled to a reference voltage, and an output of the operational amplifier being coupled to a gate electrode of the regulation transistor.

22. The memory device as claimed in claim 13, wherein the memory device further comprises a multiplexing unit connected between the evaluation unit and resistive memory cells.

23. The memory device as claimed in claim 13, wherein the resistive memory element of the resistive memory cell is coupled to the bit line and the selection transistor, and the selection transistor being further coupled to the word line and to the reference electrode.

24. An integrated circuit, comprising:
a programmable resistance element configured to switch between a low-resistive state and a high-resistive state, each state corresponding to a binary state and each state being set by application of a predefined voltage; and
a voltage regulation circuit coupled to the programmable resistance element and configured to regulate a voltage applied to the programmable resistance element with respect to a target voltage.

25. The integrated circuit as claimed in claim 24, wherein the voltage regulation circuit raises the applied voltage to a target voltage when the programmable resistance element is in the low-resistive state.

26. The integrated circuit as claimed in claim 24, wherein the target voltage is in a range of ±30% of the applied voltage when the programmable resistance element is in the high-resistive state.

27. The integrated circuit as claimed in claim 24, wherein the target voltage is in a range of ±15% of the applied voltage when the programmable resistance element is in the high-resistive state.

28. The integrated circuit as claimed in claim 24, wherein the target voltage is in a range of ±8% of the applied voltage when the programmable resistance element is in the high-resistive state.

29. The integrated circuit as claimed in claim 24, wherein the voltage regulation circuit comprises a comparator circuit which compares the applied voltage to a reference voltage to adjust the applied voltage.

30. The integrated circuit as claimed in claim 24, wherein the voltage regulation circuit comprises a regulation transistor.

31. The integrated circuit as claimed in claim 29, wherein the comparator circuit comprises a regulation transistor and an operational amplifier, a first input of the operational amplifier being coupled to the applied voltage via a feedback line, a second input of the operational amplifier being coupled to a reference voltage, and an output of the operational amplifier being coupled to a gate electrode of the regulation transistor.

32. A method of evaluating a resistive state of a resistive memory cell, comprising:
applying a sense voltage to the resistive memory cell, wherein the resistive memory cell is configured to switch between a low-resistive state and a high-resistive state, each state corresponding to a binary state and each state being set by application of a predefined voltage;
measuring the applied sense voltage at the resistive memory cell;
comparing the measured sense voltage to a reference voltage; and
on the basis of the comparison, adjusting the sense voltage with respect to a target voltage.

33. The method as claimed in claim 32, wherein, adjusting comprises raising the sense voltage to a target voltage if the resistive memory cell is in the low-resistive state.

34. The method as claimed in claim 32, wherein the target voltage is in a range of ±30% of the reference voltage.

35. The method as claimed in claim 32, wherein the target voltage is in a range of ±15% of the reference voltage.

36. The method as claimed in claim 32, wherein the target voltage is in a range of ±8% of the reference voltage.

37. The method as claimed in claim 32, wherein adjusting the sense voltage comprises controlling an evaluation unit configured to control the sense voltage.
